(19) United States
(12) Patent Application Publication
(10) Pub. No.: US 2025/0316324 A1
(43) Pub. Date: Oct. 9, 2025

(54) QUICK POWER ON BLOCK FAMILY ERROR AVOIDANCE SCAN

(71) Applicant: Micron Technology, Inc., Boise, ID (US)

(72) Inventors: Yuqi Zhu, Milpitas, CA (US); Guang Hu, Mountain View, CA (US); Chun Sum Yeung, San Jose, CA (US); Ting Luo, Santa Clara, CA (US)

(21) Appl. No.: 19/171,978

(22) Filed: Apr. 7, 2025

Related U.S. Application Data
(60) Provisional application No. 63/631,647, filed on Apr. 9, 2024.

(51) Int. Cl. G11C 29/52; G11C 16/32; G11C 16/34

(52) U.S. Cl. CPC G11C 29/52; G11C 16/32; G11C 16/349

(57) ABSTRACT

A scan pool comprising a set of blocks of a memory device is generated. Each block in the set of blocks is classified into one of multiple predefined bins and each bin of the multiple bins have a corresponding set of read level voltage offsets. Scan targets for a first bin of the multiple predefined bins are determined based on the scan pool. The scan targets include a first block, a second block, and a third block from a subset of blocks from the set of blocks that are classified into the first bin. Block family error avoidance (BFEA) scans are performed on only the scan targets. Bin classifications for other blocks in the subset of blocks are updated based on a result of the BFEA scans on only the scan targets.

### PRIORITY APPLICATION

This application claims the benefit of priority to U.S. Provisional Application Ser. No. 63/631,647, filed Apr. 9, 2024, which is incorporated herein by reference in its entirety.

### TECHNICAL FIELD

Embodiments of the disclosure relate generally to memory sub-systems and, more specifically, to techniques for performing a quick block family error avoidance (BFEA) scan at power on of a memory device.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system, in accordance with some embodiments of the present disclosure.

FIG. 2 is data flow diagrams illustrating interactions between components in the memory sub-system in performing an example BFEA scan method at power on, in accordance with some embodiments of the present disclosure.

FIGS. 3 and 4 are flow diagrams illustrating an example method for performing a BFEA scan on a memory device at power on, in accordance with some embodiments of the present disclosure.

FIG. 5 is a block diagram of an example computer system in which embodiments of the present disclosure may operate.

### DETAILED DESCRIPTION

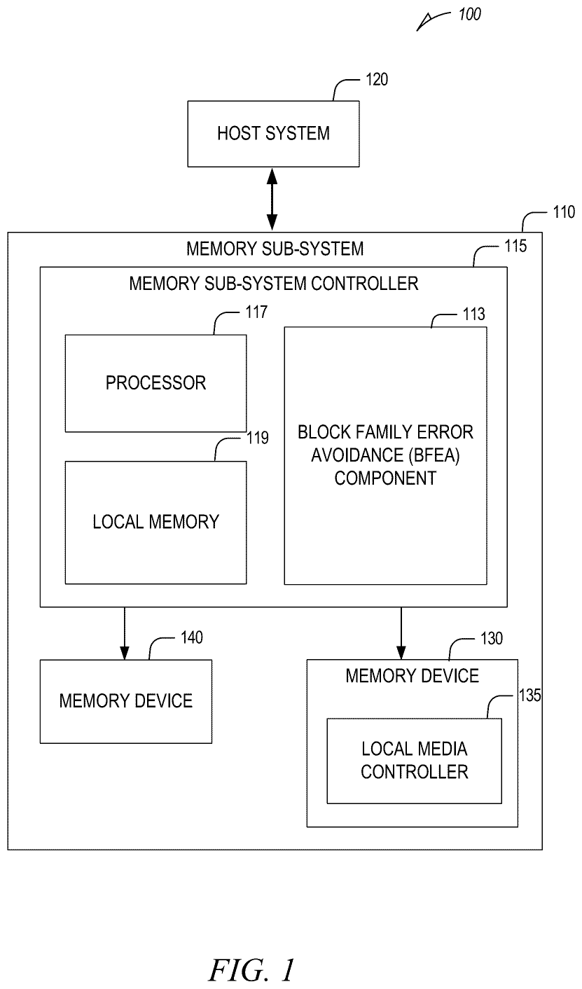

Aspects of the present disclosure are directed to an approach for performing a quick block family error avoidance (BFEA) scan at power on of a memory device of a memory sub-system. A memory sub-system can be a storage device (e.g., solid-state drive [SSD]), a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system. A memory sub-system controller typically receives commands or operations from the host system and converts the commands or operations into instructions or appropriate commands to achieve the desired access to the memory components of the memory sub-system.

A memory device can be a non-volatile memory device. One example of a non-volatile memory device is a negative-and (NAND) memory device. A NAND memory device can include multiple NAND dies. Each die may include one or more planes and each plane includes multiple blocks. Each block includes an array that includes pages (rows) and strings (columns). A string includes a plurality of memory cells connected in series. A memory cell (also referred to herein simply as a “cell”) is an electronic circuit that stores information. Depending on the cell type, a cell can store one or more bits of binary information and has various logic states that correlate to the number of bits being stored. The logic states can be represented by binary values, such as “0” and “1,” or combinations of such values.

Various memory access operations can be performed on the memory cells. Data can be written to, read from, and erased from memory cells. Memory cells can be grouped into a write unit, such as a page. For some types of memory devices, a page is the smallest write unit. A page size represents a particular number of cells of a page. Data can be written to a block, page-by-page. During write operations, data is programmed into a block of the memory device using a programming sequence that includes multiple passes in which programming pulses are applied to cells in the block. Over the multiple passes, the programming pulses configure the threshold voltages (Vt) of the cells in each page according to the value that the cells are intended to represent. As the programming sequence progresses, the voltage level of the programming pulses increase until a target voltage level for each cell is reached.

The Vt distribution of a memory cell can be divided into a number of regions based on the number of bits stored by the cell where each region corresponds to a value that can be represented by the cell. More specifically, each region corresponds to a read level and each read level decodes into a multi-bit value. For example, a TLC NAND flash cell can be at one of eight charge levels (L0, L1, L2, L3, L4, L5, L6, or L7) and each charge level decodes into a 3-bit value that is stored in the flash cell (e.g., 111, 110, 100, 000, 010, 011, 001, and 101).

For memory devices such as a NAND-based memory device, Slow Charge Loss (SCL) of memory cells is a major degradation mechanism for data retention (DR). In particular, due to the effects of SCL, memory cells have their Vt distributions lose charge, with the highest Vt distributions typically losing charge faster than lower Vt distributions. SCL is usually a function of time and temperature, and can also be susceptible to other factors, such as cycling degradation (e.g., more Vt distribution shift for End of Life (EOL) blocks than for Beginning of Life (BOL) blocks). SCL usually causes a memory cell's Vt distribution to shift lower (e.g., causes the Vt distribution valley to shift lower) right after the memory cell is programmed.

Generally, to read data from a memory cell, one or more read level voltages are applied to the gate of a transistor (of the memory cell) to determine (e.g., sense) the value of the current threshold voltage (e.g., the voltage at which the transistor conducts current), and the current threshold voltage value can be decoded (e.g., mapped) to a data value (e.g., bit string) stored by the memory cell. To compensate for SCL-based shift when performing a read operation on a memory cell, an offset (or read level voltage offset) is usually applied to one or more read level voltages (also referred to herein as read levels) used to read data from the memory cell. Traditionally, the read level voltage offset applied to a memory cell is determined based on SCL tracking. Tracking SCL of memory cells is crucial to avoiding excessive latency impact, which can be caused by unnecessary error handling that results from incorrect read level placement (which can occur if a read level voltage offset applied to a read level voltage causes it to be placed without considering SCL effect on Vt distributions). Intrinsically, the effects of SCL on a memory cell hold strong dependence on a wordline (WL) group of the memory cell due to process variation (process variation that existed when the memory cell was manufactured) and asymmetric bitline (BL) cross-section at each WL. For instance, the cross-section can be larger at the top of the WL of each deck and yield smaller effective field, or the cross-section can be smaller at the bottom of the WL of each deck and yield stronger effective field. Accordingly, traditional methods for SCL tracking include performing periodic, proactive scans of blocks (comprising memory cells) and classify measured read level voltage offsets of scanned blocks into one of multiple predefined bins. Blocks with similar SCL characteristics can be grouped together in a bin to improve the management efficiency.

As an example, a block family error avoidance (BFEA) algorithm (one example of SCL tracking) can scan blocks to determine a shift of read level 7 (LVL7 or L7). The determined shift of read level 7 can be categorized into a specific bin (e.g., BFEA bin), read level voltage offsets for read levels 1 through 7 can be determined from a look-up table (LUT) (e.g., BFEA LUT) based on the specific bin (e.g., from a column of the LUT corresponding to the specific bin), and the determined read level voltage offsets can be used in a read operation (e.g., host reads) for one or more of those blocks. For example, if the shift of read level 7 of a memory cell is −23 characterized by BFEA scan, the BFEA algorithm can determine (e.g., identify) a bin (e.g., BFEA bin) that is associated with the shift of −23 (e.g., bin 5 based on example Table 1, provided below), can determine read level voltage offsets for read levels 1 through 7 from the LUT (e.g., read level voltage offsets of bin 5's column of example Table 2, provided below) based on the determined bin (e.g., column associated with the bin), and can use the one or more determined read level voltage offsets in connection with a read operation for the memory cell.

TABLE 1

| BIN | 1 | 2 | 3 | 4 | 5 | 6 | 7 |
|---|---|---|---|---|---|---|---|
| Shift | [−3, | [−9, | [−14, | [−17, | [−22, | [−27, | [−33, |
| range | −8] | −13] | −16] | −21] | −26] | −32] | −>] |

TABLE 2

| BIN | 1 | 2 | 3 | 4 | 5 | 6 | 7 |
|---|---|---|---|---|---|---|---|
| LVL1 | | | | | | | |
| LVL2 | −1 | −2 | −2 | −3 | −4 | −4 | −5 |
| LVL3 | −2 | −4 | −4 | −6 | −8 | −8 | −9 |
| LVL4 | −2 | −4 | −6 | −6 | −8 | −11 | −13 |
| LVL5 | −3 | −6 | −7 | −9 | −12 | −14 | −17 |
| LVL6 | −4 | −8 | −10 | −12 | −16 | −20 | −23 |
| LVL7 | −6 | −12 | −15 | −18 | −24 | −30 | −36 |

BFEA scans, as described above, can be executed at power on of a memory device and/or during normal operation of the memory device. BFEA scans performed at power on are resource intensive and often result in a negative impact to system performance, especially in instances where there insufficient idle time for a BFEA component to correctly determine bin classifications for all blocks of a memory device, which can result in boot up latency issues.

Aspects of the present disclosure address the above and other issues with conventional BFEA scan techniques, by performing a quick power on BFEA scan based on scan priority of blocks determined by a first-in-first-out (FIFO) queue. In the context of the FIFO queue, the magnitude of determined read level voltage offsets for a given block is assumed to be proportional to the time since the last BFEA scan was performed on the block (referred to herein as “drift time”). Hence, blocks within the same bin in the FIFO queue (also referred to herein as a “scan queue”) are in descending order based on drift time. At power on, a selection of scan targets are selected for a given bin, a BFEA scan is performed on only the scan targets, and the result of the BFEA scan on the scan targets is used to update bin classifications for other blocks classified into the bin. The scan targets are selected from a scan pool generated based on the scan queue based on drift time. In an example, a BFEA component identifies, for a given bin, three blocks as scan targets: a first block having the highest drift time for blocks in the bin, a second block having a lowest drift time of blocks in the BIN, and a third block having a drift time that is between the highest drift time and lowest drift time. Thus, the BFEA component is able to provide updated bin classifications for all blocks while only actually scanning a small subset of blocks thereby reducing the number of total scans needed to update bin classifications. Hence, performing power on BFEA scans in this manner provides a quick bin update for all blocks with reasonable accuracy while avoiding boot up latency issues that frequently occur in traditional power on BFEA scan methods.

FIG. 1 illustrates an example computing environment 100 that includes a memory sub-system 110, in accordance with some embodiments of the present disclosure.

The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, and so forth.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize a Non-Volatile Memory Express (NVMe) interface to access the memory devices 130 and 140 when the memory sub-system 110 is coupled with the host system 120 by the PCIe or CXL interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130) includes a NAND type flash memory. Each of the memory devices 130 can include one or more arrays of memory cells such as single level cells (SLCs), multi-level cells (MLCs) (e.g., triple level cells (TLCs), or quad-level cells (QLCs)). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), NOR flash memory, electrically erasable programmable read-only memory (EEPROM), and a cross-point array of non-volatile memory cells. A cross-point array of non-volatile memory can perform bit storage based on a change of bulk resistance in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 115 can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and the like. The local memory 119 can also include ROM for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 and convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130.

The memory sub-system 110 also includes a BFEA component 113 that is responsible for performing BFEA scans on the memory device 130 and the memory device 140. The BFEA component 113 utilizes a FIFO scan queue to track scan priority of blocks. As an example, during normal operation of the memory sub-system 110, the BFEA component 113 scans blocks of the memory device 130 in an order based on the scan queue. That is, the BFEA component 113 scans the first block in scan queue and when the scan is complete, the BFEA component 113 removes the block from the scan queue for a predetermined period of time before adding the block to the end of the scan queue. In performing a BFEA scan on a given block, the BFEA component 113 classifies the block into one of multiple predefined bins based on determined read level 7 shift for the block. Read level offsets for each read level of the block can be determined from a LUT based on the bin the block is classified into and the read level offsets can be applied during read operations directed at the block.

During power on of the memory sub-system controller 115, the BFEA component updates bin classifications for the blocks of the memory device 130 based on a BFEA scan of scan targets selected for each bin. For a given bin, the scan targets comprise a subset of the blocks categorized into the bin. Based on the bin classifications determined for the scan targets for a particular bin from the BFEA scan, the BFEA component 113 updates bin classifications of the other blocks categorized into the bin.

In some embodiments, the memory sub-system controller 115 includes at least a portion of the BFEA component 113. For example, the memory sub-system controller 115 can include a processor 117 (processing device) configured to execute instructions stored in local memory 119 (e.g., firmware) for performing the operations described herein. In some embodiments, the BFEA component 113 is part of the host system 120, an application, or an operating system. Further details regarding the BFEA component 113 are discussed below.

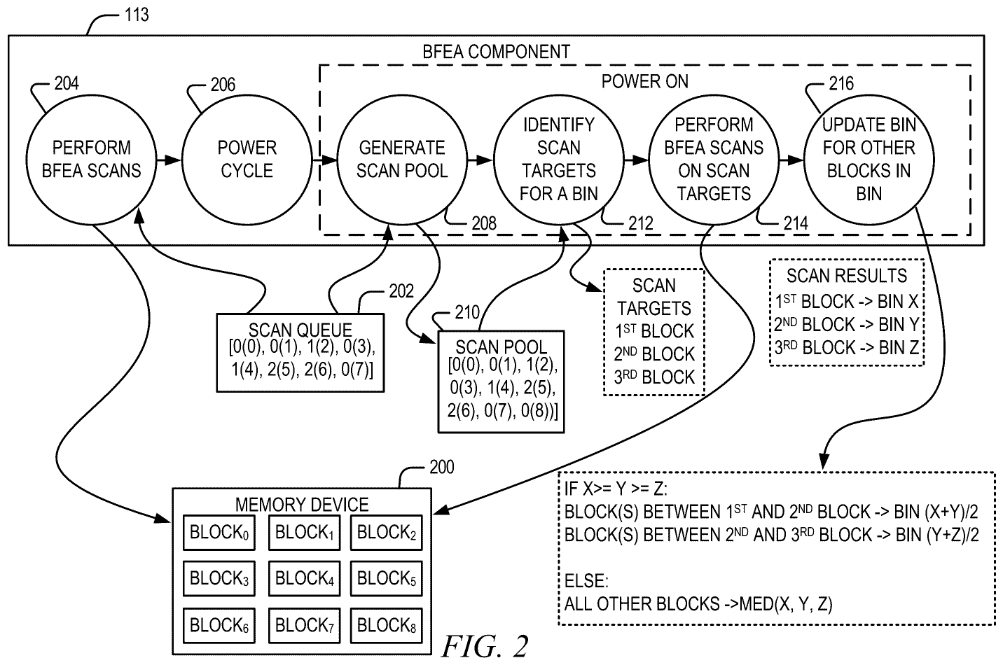

FIG. 2 is a data flow diagram illustrating interactions between components of the memory sub-system 110 in performing an example method for a power on BFEA scan of a memory device 200, in accordance with some embodiments of the present disclosure. In the example illustrated in FIG. 2, the memory device 200 is an example memory device 130 in the example form of a NAND memory device.

The memory device 200 includes multiple NAND dies. Each die may include one or more planes and each plane includes multiple blocks such as block₀-block₈ illustrated in FIG. 2. Each block includes a two or three dimensional array that includes pages (rows) and strings (columns). A string includes a plurality of memory cells connected in series. Each memory cell is used to represent one or more bit values. For example, a single NAND flash cell includes a transistor that stores an electric charge on a memory layer that is isolated by oxide insulating layers above and below. Within each cell, data is stored as the threshold voltage of the transistor. SLC NAND, for example, can store one bit per cell. Other types of memory cells, such as MLCs, TLCs, QLCs, and PLCs, can store multiple bits per cell. In this example, the NAND memory includes an SLC portion that includes multiple SLCs and a QLC portion that includes multiple QLCs.

As noted above, each NAND cell stores data in the form of the threshold voltage (V_{T}) of the transistor. The range of threshold voltages of a memory cell can be divided into a number of regions based on the number of bits stored by the cell where each region corresponds to a value that can be represented by the cell. More specifically, each region corresponds to a read voltage level (also referred to simply as “read level”) and each read voltage level decodes into a multi-bit value. For example, a TLC NAND flash cell can be at one of eight read levels (L0, L1, L2, L3, L4, L5, L6, or L7) and each read level decodes into a 3-bit value that is stored in the flash cell (e.g., 111, 110, 100, 000, 010, 011, 001, and 101).

In the context of FIG. 2, a scan queue 202 implemented as a FIFO queue is used track and manage BFEA scan priority (also referred to herein as “scan order”) for blocks of the memory device 200. The scan queue 202 is stored in nonvolatile memory (e.g., local memory 119) such that the scan queue 202 is persisted upon a power cycle of the memory sub-system 110. Blocks within the same bin in the scan queue 202 are sorted in descending order based on drift time, where the magnitude of the read level voltage offsets is assumed to be proportional to the drift time of each block since the last BFEA scan performed at each bin. The BFEA component 113 performs a BFEA scan on the first block in the scan queue 202, and once a given block is scanned, the block is initially removed from the scan queue 202 and later added to the end of the scan queue 202 after a predetermined time period. The predetermined time period may be based on the bin in which the block is classified. For example, blocks within bins 0-3 may be added to the end of the scan queue 202 after 1 hour, while blocks within bin 4-7 may be added to the end of the scan queue 202 after 24 hours. In an example of the foregoing in which the notation “bin #(block #)” is used, the scan queue 202 comprises:
[0(0),0(1),1(2),0(3),1(4),2(5),2(6),0(7)]

As shown, BFEA scans are performed by the BFEA component 113 on the blocks of the memory device 130, at 204. The BFEA component 113 scans the blocks of the memory device 130 in order based on the scan priority defined by the scan queue 202. In particular, the BFEA component 113 scans the first block in the scan queue 202, which in the example above is block₀, and once the scan is complete the BFEA component 113 removes the block from the scan queue 202, which in the example above results in the following:
[0(1),1(2),0(3),1(4),2(5),2(6),0(7)]

In a subsequent scan, the BFEA component 113 again scans the first block in the scan queue 202, which is now block₁, and block₁ is removed from the scan queue 202 after the BFEA scan is complete, which results in the following scan queue 202:
[1(2),0(3),1(4),2(5),2(6),0(7)]

After a predetermined period of time (e.g., 1 hr), block₀ is added back to the end of the scan queue 202, which, assuming the BFEA scan of block₀ results in a determination of block₀ being classified in bin 1, results in the following for the scan queue 202:
[1(2),0(3),1(4),2(5),2(6),0(7),1(0)]

In performing a BFEA scan on a given block of the memory device 200, the BFEA component 113 scans the block to determine the shift of read level 7 and the block is categorized into a predetermined bin based on determined shift of read level 7. Read level voltage offsets for read levels 1 through 7 for a given block can be determined from a look-up table (LUT) (e.g., table 2) based on the specific bin (e.g., from a column of the LUT corresponding to the specific bin) to which the block is categorized.

Subsequent to the BFEA scan, a power cycle 206 of the memory sub-system 110 occurs. During power up of the memory sub-system 110, the BFEA component 113 generates a scan pool 210 comprising a set of blocks of from the memory device 200 (operation 208). To generate the scan pool 210, the BFEA component 113 appends one or more other blocks to the scan queue 202, which in the example illustrated in FIG. 2 is block₈ and results in the following:
[0(0),0(1),1(2),0(3),1(4),2(5),2(6),0(7), 0(8)]

The scan queue 202 is persistently stored prior to power down of the memory sub-system. The one or more other blocks include blocks removed from the scan queue subsequent to a BFEA scan being performed. Hence, given the scan pool is generated based on the scan queue 202 in this manner, the scan pool also functions as a FIFO queue and maintains the scan priority defined by the scan queue 202 with the addition of the one or more other blocks.

At operation 212, the BFEA component 113 identifies scan targets for a bin (e.g., Bin0) among the multiple predefined bins from the scan pool 210. The BFEA component 113 identifies the scan targets from a subset of blocks of the memory device 200 that are classified into the bin. For example, for bin 0, the BFEA component 113 identifies scan targets from blocks 0, 1, 3, 7, and 8. The scan targets for the first bin include the block in the first bin with the highest drift time (a first block), a block in the first bin with a drift time that is between the highest drift time and the lowest drift time (a second block), and the block in the first bin with lowest drift time (a third block). Following the example of bin 0, the BFEA component 113 selects block₀ (highest drift time), block₃ (medium drift time), and blocks (lowest drift time) as scan targets.

The BFEA component 113, at operation 214, performs a BFEA scan on only the bin scan targets, at operation 214. Following the example of bin 0, the BFEA component 113 performs BFEA scans on block₀, block₃, and blocks. In performing the BFEA scans, the BFEA component 113 determines updated bin classifications for the first, second, and third block based on respective read level 7 shifts of the first, second, and third blocks. In a general example, the BFEA component 113 classifies: the first block into bin X, the second block into bin Y, and the third block into bin Z. In the more specific example of bin 0, the BFEA component 113 classifies: the block₀ into bin X, the block₃ into bin Y, and blocks into bin Z.

At operation 216, the BFEA component 113 updates bin classifications of the other subset of blocks in the bin based on a result of the BFEA scan on only the first bin scan targets. That is, the BFEA component 113 updates bin classifications for blocks in the subset of blocks other than the first block, the second block, and the third block. Following the example of bin 0, the BFEA component 113 updates bin classifications for block₁ and block₇ based on the result of the BFEA scan on only block₀, block₃, and blocks.

In an example of the updating of bin classifications, the BFEA component 113 determines whether bin number X is greater than or equal to bin number Y and whether bin number Y is greater than or equal to bin number Z (X>=Y>=Z). If X>=Y>=Z, the BFEA component 113 classifies blocks that are between the first block and the second block in the scan order of the scan queue 202 into bin ((X+Y)/2) (the average of the bin numbers X and Y) and the BFEA component 113 classifies blocks that are between the second block and the third block in the scan queue 202 into bin ((Y+Z)/2) (the average of the bin numbers Y and Z). in the more specific example of bin 0, the BFEA component classifies block₁ into bin ((X+Y)/2) and classifies block₇ into bin ((Y+Z)/2)

If bin number X is less than bin number Y (X<Y) or if bin Y is less than bin Z (Y<Z), the BFEA component 113 classifies other blocks in the subset of blocks into a bin determined based on a median of bin numbers X, Y, and Z. In the example of bin 0, the BFEA component 113 classifies block₁ and block₇ into the bin corresponding to the median X, Y, and Z.

The BFEA component 113 repeats the operations 212, 214, and 216 for each bin among the multiple bins (e.g., each of bins 1-7 of Tables 1 and 2). That is, the BFEA component 113 identifies scan targets for each bin, performs BFEA scans on only the scan targets for each bin, and updates bin classifications for other blocks of each bin based on the result of the BFEA scans on the scan targets for the bin.

Read level voltage offsets can be determined for any one or more of the blocks in the memory device 130 based on the updated bin classifications determined at operation 216, for example, based on a LUT (e.g., Table 2) and the read level voltage offsets can be applied to one or more read operations directed at the block.

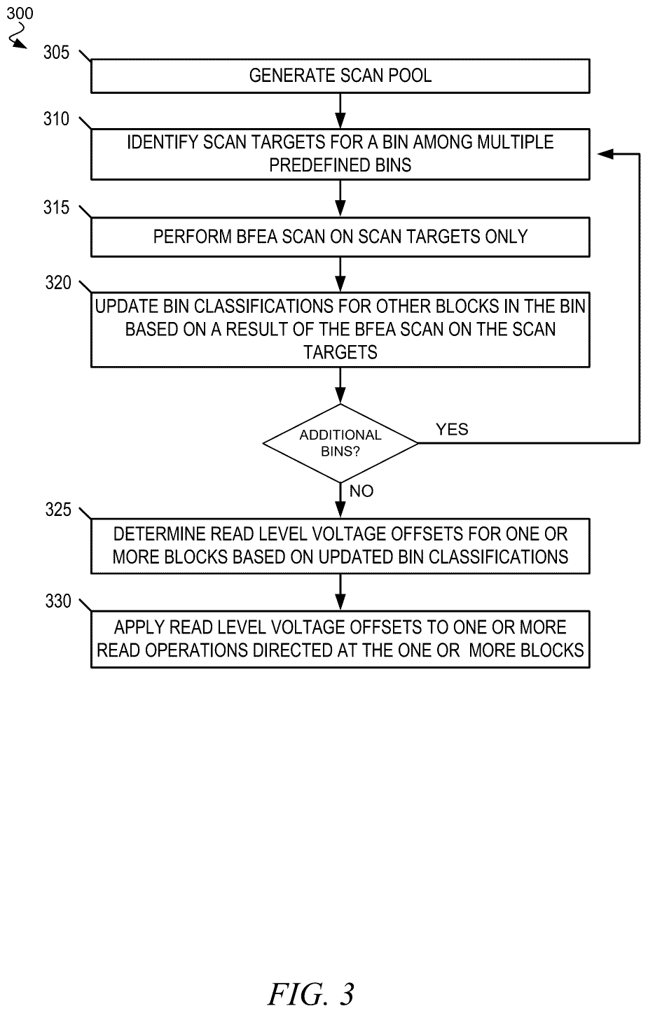

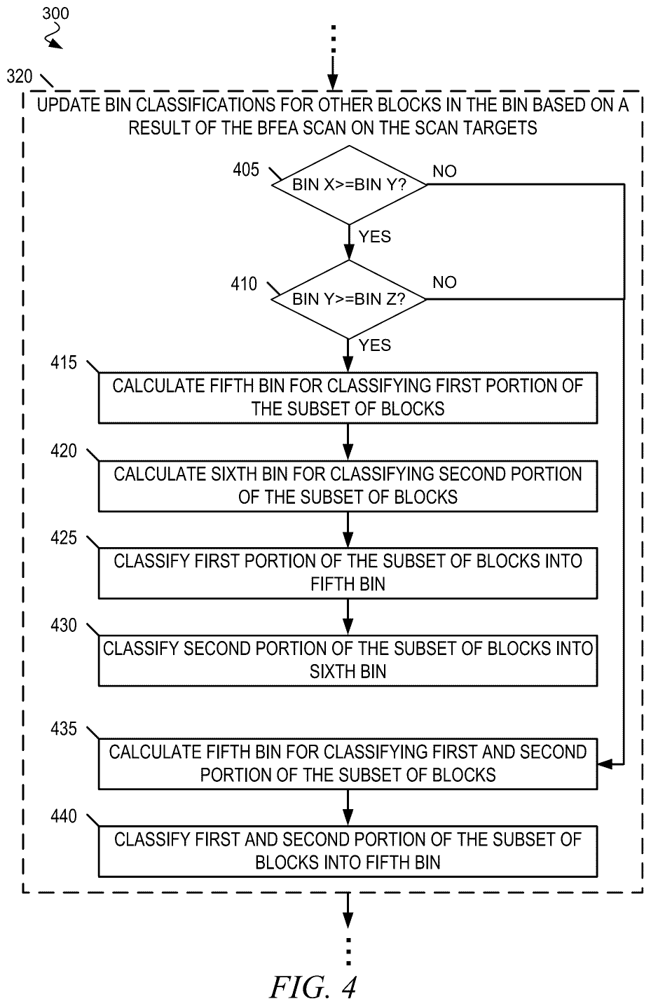

FIGS. 3 and 4 are flow diagrams illustrating an example method 300 for performing a BFEA scan at power on, in accordance with some embodiments of the present disclosure. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some embodiments, the method 300 is performed by the BFEA component 113 of FIG. 1. Although processes are shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

For some examples, the method 300 is initiated at power up of the memory sub-system. At operation 305, the processing device generates a scan pool comprising a set of blocks of a memory device (e.g., the memory device 130). Each block in the set of blocks is classified into a bin from among multiple predefined bins based on read level shifts of the set of blocks (e.g., a shift of read level 7). Each bin has a corresponding read level voltage offset to apply to blocks in the bin. The bins classifications for each block in the set of blocks are determined based on a BFEA scan performed prior to power down of the memory sub-system. During the BFEA scan, the set of blocks are scanned to determine the shift of read level 7 (LVL7 or L7) and the determined shift of read level 7 of each block is categorized into a specific bin (e.g., BFEA bin) among the multiple predefined bins. Read level voltage offsets for read levels 1 through 7 can be determined for each block from a look-up table (LUT) based on the specific bin (e.g., from a column of the LUT corresponding to the specific bin).

To generate the scan pool, the processing device access a scan queue from memory and appends one or more other blocks to the scan queue. The scan queue is persistently stored prior to power down of the memory sub-system. The scan queue comprises multiple blocks ordered sequentially based on block number and the order of the scan queue defines a scan order for BFEA scans. The one or more other blocks can include blocks removed from the scan queue.

At operation 310, the processing device identifies scan targets for a first bin (e.g., Bin0) among the multiple predefined bins. The scan targets include a first block, a second block, and a third block from a subset of blocks from the set of blocks that are classified into the first bin. The processing device identifies the scan targets based on a drift time of each block determined based on the order of the scan queue. More specifically, the processing device identifies the block with the highest drift time (the first block), the block with lowest drift time (the third block) and a block with a drift time that is between the highest drift time and the lowest drift time.

At operation 315, the processing device performs BFEA scans on only the scan targets for the first bin. In performing the BFEA scans, the processing device determines updated bin associations for the first, second, and third block. In an example, the processing device classifies the first block into a second bin, classifies the second block into a third bin, and classifies the third block into a fourth bin.

At operation 320, the processing device updates bin classifications of the other subset of blocks based on a result of the BFEA scans on only the scan targets for the first bin. That is, the processing device updates bin classifications for blocks in the subset of blocks other than the first block, the second block, and the third block based on the BFEA scans of only the first block, the second block, and the third block. Further details regarding the updating of the bin classifications for the other blocks classified within the bin are discussed below.

As shown, the processing device repeats the operations 310, 315, and 320 for each bin of the multiple predefined bins such that for each bin scan targets are identified and scanned and the result of the scan on only the scan targets is used to update bin classifications for the other blocks categorized into the bin. As an example, the processing device can identify scan targets for a second bin from blocks categorized within the second bin, perform a BFEA scan on only the scan targets for the second bin, and update bin classifications for other blocks categorized into the second bin based on a result of the BFEA scan on only the scan targets for the second bin.

At operation 325, the processing device determines read level voltage offsets for one or more blocks in the memory device based on the updated bin classifications (performed at operation 320) and the processing device applies the read level voltage offsets in one or more read operations directed at the one or more blocks, at operation 330. In an example, the processing device updates the bin classification of a fourth block such that the fourth block is associated with the fifth bin (e.g., Bin 4). The processing device can determine read level voltage offsets for read levels 1 through 7 for the block from a LUT (e.g., read level voltage offsets of bin 4's column of example Table 2, provided above) based on the bin classification use the one or more determined read level voltage offsets in connection with a read operation for the fourth block.

As shown in FIG. 4, the method 300 can, in some embodiments, include operations 405, 410, 415, 420, 425, 430, 435, and 440. Consistent with these embodiments, the operations 405, 410, 415, 420, 425, 430, 435, and 440 may be performed as part of operation 320 where the processing device updates bin classifications of the subset of bins based on a result of the BFEA scan on only the scan targets for the first bin.

At operation 405, the processing device determines whether the second bin number (represented as “bin X” in FIG. 4) is greater than or equal to the third bin number (represented as “bin Y” in FIG. 4) and at operation 410, the processing device determines whether the third bin number is greater than or equal to the fourth bin number (represented as “bin Z” in FIG. 4).

Based on determining the second bin number is greater than or equal to the third bin number and determining the third bin number is greater than or equal to the fourth bin number, the processing device, at operation 415, calculates a fifth bin for classifying a first portion of the subset of blocks and at operation 420, the processing device calculates a sixth bin for classifying a second portion of the subset of blocks. The first portion of the subset of blocks corresponds to blocks that are between the first block and the second block in the scan order of the scan queue and the second portion of the subset of blocks corresponds to blocks that are between the second block and the third block in the scan order of the scan queue. In an example, the processing device calculates the fifth bin by determining an average of the second bin number and the third bin number and the processing device calculates the sixth bin by determining an average of the third bin number and the fourth bin number.

The processing device classifies the first portion of the subset of blocks into the fifth bin (operation 425) and classifies the second portion of the subset of blocks into the sixth bin (operation 430).

Based on determining that the second bin number is less than the third bin number or determining that the third bin number is less than the fourth bin number, the processing device determines a fifth bin to associate with other blocks in the subset (the blocks in the subset of blocks other than the first block, the second block, and the third block), at operation 435. In an example, the processing device determines the fifth bin by determining based on a median of: the second bin number, the third bin number, and the fourth bin number. The processing device, classifies the other blocks in the subset of blocks into the fifth bin, at operation 440.

Described implementations of the subject matter can include one or more features, alone or in combination as illustrated below by way of example.

Example 1. A memory sub-system comprising: a memory device; and a processing device, operatively coupled with the memory device to perform operations comprising: generating a scan pool comprising a set of blocks of the memory device, each block in the set of blocks being classified into one of multiple predefined bins based on determined read level shifts of the set of blocks, each bin of the multiple bins having a corresponding set of read level voltage offsets; identifying scan targets for a first bin of the multiple predefined bins based on the scan pool, the scan targets including a first block, a second block, and a third block from a subset of blocks from the set of blocks that are classified into the first bin; performing block family error avoidance (BFEA) scans on only the scan targets; and updating bin classifications for other blocks in the subset of blocks based on a result of the BFEA scan on only the scan targets.

Example 2. The memory sub-system of Example 1, wherein generating the scan pool comprises: accessing a scan queue comprising multiple blocks, the scan queue defining a scan order for BFEA scans; and appending one or more other blocks to the scan queue.

Example 3. The memory sub-system of any one or more of Examples 1 or 2, wherein: the generating of the scan pool is performed upon power up of the memory sub-system; and the scan queue is persistently stored prior to power down of the memory sub-system.

Example 4. The memory sub-system of any one or more of Examples 1-3, wherein determining the scan targets for the first bin comprises: identifying the subset of blocks from the set of blocks that are classified into the first bin; identifying a first block from the subset of blocks having a first drift time; identifying a second block from the subset of blocks having a second drift time, the second drift time being less than the first drift time; and identifying a third block from the subset of blocks having a third drift time, the third drift time being less than the second drift time; wherein the first drift time, the second drift time, and the third drift time are based on a scan order of the set of blocks.

Example 5. The memory sub-system any one or more of Examples 1-4, wherein: the first drift time is a highest drift time among the subset of blocks classified into the first bin; and the second drift time is a lowest drift time among the subset of blocks classified into the first bin.

Example 6. The memory sub-system of any one or more of Examples 1-5, wherein the performing of the BFEA scans on the scan targets comprises determining updated bin classifications for each of the first block, the second block, and the third block.

Example 7. The memory sub-system of any one or more of Examples 1-6, wherein the determining of the updated bin classifications for each of the first block, the second block, and the third block comprises: classifying the first block into a second bin; classifying the second block into a third bin; and classifying the third block into a fourth bin.

Example 8. The memory sub-system of any one or more of Examples 1-7, wherein the updating of the bin classifications for other blocks in the subset of blocks comprises: determining a second bin number corresponding to the second bin is greater than or equal to a third bin number corresponding to the third bin; determining the third bin number is greater than or equal to a fourth bin number corresponding to the fourth bin; and based on determining the second bin number is greater than or equal to the third bin number and determining the third bin number is greater than or equal to the fourth bin number, calculating a fifth bin for classifying a first portion of the subset of blocks based on an average of the second bin number and the third bin number; classifying the first portion of the subset of blocks into the fifth bin; calculating a sixth bin for classifying a second portion of the subset of blocks based on an average of the third bin number and the fourth bin number; classifying the second portion of the subset of blocks into the sixth bin.

Example 9. The memory sub-system of any one or more of Examples 1-8, wherein the updating of the bin classifications for other blocks in the subset of blocks comprises: based on determining that a second bin number corresponding to the second bin is less than a third bin number corresponding to the third bin or that the third bin number is less than a fourth bin number corresponding to the fourth bin, calculating a fifth bin to associate with other blocks in the subset based on a median of: the second bin number, the third bin number, and the fourth bin number; and classifying the other blocks in the subset of blocks with the fifth bin.

Example 10. The memory sub-system of any one or more of Examples 1-9, wherein the operations further comprise: determining read level voltage offsets for a block in the subset of blocks based on the updated bin classifications; and applying the read level voltage offsets in one or more read operations directed at the block.

Example 11. The memory sub-system of any one or more of Examples 1-10, wherein: the scan targets are first scan targets; the subset of blocks is a first subset of blocks; and the operations further comprise: identifying second scan targets corresponding to a second bin of the multiple bins based on the scan pool, the second scan targets including a fourth block, a fifth block, and a sixth block from a second subset of blocks from the set of blocks that are associated with the second bin; performing BFEA scans on the second scan targets; and updating bin classifications for other blocks in the second subset of blocks based on a result of the BFEA scans on only the second scan targets.

Example 12. A method comprising: generating, by a processing device, a scan pool comprising a set of blocks of a memory device, each block in the set of blocks being classified into one of multiple predefined bins based on determined read level shifts of the set of blocks, each bin of the multiple bins having a corresponding set of read level voltage offsets; identifying, by the processing device, scan targets for a first bin of the multiple predefined bins based on the scan pool, the scan targets including a first block, a second block, and a third block from a subset of blocks from the set of blocks that are classified into the first bin; performing, by the processing device, block family error avoidance (BFEA) scans on only the scan targets; and updating, by the processing device, bin classifications for other blocks in the subset of blocks based on a result of the BFEA scans on only the scan targets.

Example 13. The method of Example 12, wherein generating the scan pool comprises: accessing a scan queue comprising multiple blocks, the scan queue defining a scan order for BFEA scans; and appending one or more other blocks to the scan queue.

Example 14. The method of any one or more of Examples 12 or 13, wherein: the generating of the scan pool is performed upon system power up; and the scan queue is persistently stored prior to system power down.

Example 15. The method of any one or more of Examples 12-14, wherein determining the scan targets for the first bin comprises: identifying the subset of blocks from the set of blocks that are classified into the first bin; identifying a first block from the subset of blocks having a first drift time; identifying a second block from the subset of blocks having a second drift time, the second drift time being less than the first drift time; and identifying a third block from the subset of blocks having a third drift time, the third drift time being less than the second drift time; wherein the first drift time, the second drift time, and the third drift time are based on a scan order of the set of blocks.

Example 16. The method of any one or more of Examples 12-15, wherein: the first drift time is a highest drift time among the subset of blocks classified into the first bin; and the second drift time is a lowest drift time among the subset of blocks classified into the first bin.

Example 17. The method of any one or more of Examples 12-16, wherein the performing of the BFEA scans on the scan targets comprises: classifying the first block into a second bin; classifying the second block into a third bin; and classifying the third block into a fourth bin.

Example 18. The method of any one or more of Examples 12-17, wherein the updating of the bin classifications for other blocks in the subset of blocks comprises: determining a second bin number corresponding to the second bin is greater than or equal to a third bin number corresponding to the third bin; determining the third bin number is greater than or equal to a fourth bin number corresponding to the fourth bin; and based on determining the second bin number is greater than or equal to the third bin number and determining the third bin number is greater than or equal to the fourth bin number, calculating a fifth bin for classifying a first portion of the subset of blocks based on an average of the second bin number and the third bin number; classifying the first portion of the subset of blocks into the fifth bin; calculating a sixth bin for classifying a second portion of the subset of blocks based on an average of the third bin number and the fourth bin number; classifying the second portion of the subset of blocks into the sixth bin.

Example 19. The method of any one or more of Examples 12-18, wherein the updating of the bin classifications for other blocks in the subset of blocks comprises: based on determining that a second bin number corresponding to the second bin is less than a third bin number corresponding to the third bin or that the third bin number is less than a fourth bin number corresponding to the fourth bin, calculating a fifth bin to associate with other blocks in the subset based on a median of: the second bin number, the third bin number, and the fourth bin number; and classifying the other blocks in the subset of blocks with the fifth bin.

Example 20. A computer-readable storage medium comprising instructions that, when executed by a processing device, configure the processing device to perform operations comprising: generating a scan pool comprising a set of blocks of a memory device, each block in the set of blocks being classified into one of multiple predefined bins based on determined read level shifts of the set of blocks, each bin of the multiple bins having a corresponding set of read level voltage offsets; identifying scan targets for a first bin of the multiple predefined bins based on the scan pool, the scan targets including a first block, a second block, and a third block from a subset of blocks from the set of blocks that are classified into the first bin; performing block family error avoidance (BFEA) scans on only the scan targets; and updating bin classifications for other blocks in the subset of blocks based on a result of the BFEA scans on only the scan targets.

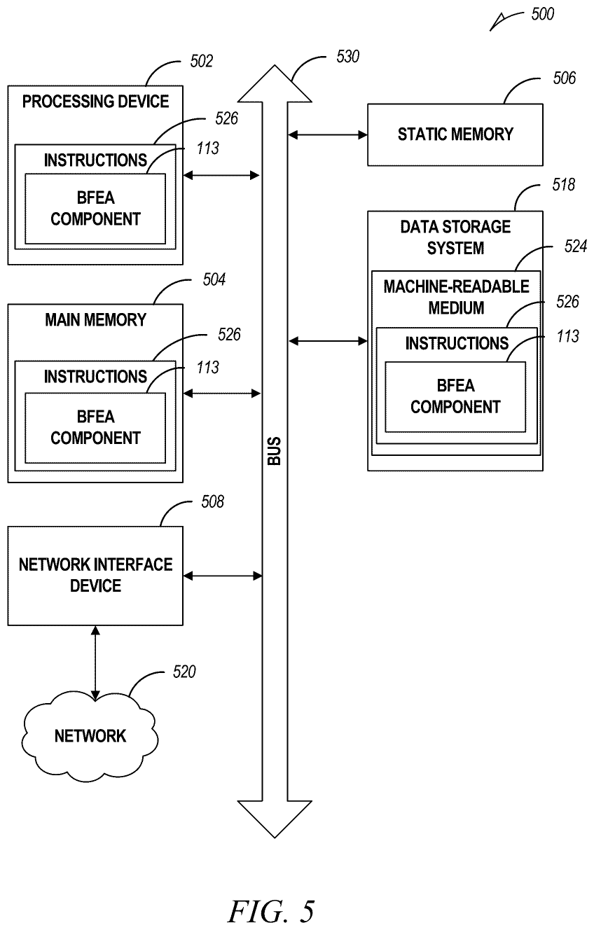

FIG. 5 illustrates an example machine in the form of a computer system within which a set of instructions can be executed for causing the machine to perform any one or more of the methodologies discussed herein. FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the BFEA component 113 of FIG. 1). In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an ASIC, a FPGA, a digital signal processor (DSP), network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a BFEA component (e.g., the BFEA component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader scope of embodiments of the disclosure as set forth in the following claims. The specification and drawings are, accordingly, to be regarded in an illustrative sense rather than a restrictive sense.

What is claimed is:

1. A memory sub-system comprising:
a memory device; and
a processing device, operatively coupled with the memory device to perform operations comprising:
generating a scan pool comprising a set of blocks of the memory device, each block in the set of blocks being classified into one of multiple predefined bins based on determined read level shifts of the set of blocks, each bin of the multiple bins having a corresponding set of read level voltage offsets;
identifying scan targets for a first bin of the multiple predefined bins based on the scan pool, the scan targets including a first block, a second block, and a third block from a subset of blocks from the set of blocks that are classified into the first bin;
performing block family error avoidance (BFEA) scans on only the scan targets; and
updating bin classifications for other blocks in the subset of blocks based on a result of the BFEA scan on only the scan targets.

2. The memory sub-system of claim 1, wherein generating the scan pool comprises:
accessing a scan queue comprising multiple blocks, the scan queue defining a scan order for BFEA scans; and
appending one or more other blocks to the scan queue.

3. The memory sub-system of claim 2, wherein:
the generating of the scan pool is performed upon power up of the memory sub-system; and
the scan queue is persistently stored prior to power down of the memory sub-system.

4. The memory sub-system of claim 1, wherein determining the scan targets for the first bin comprises:
identifying the subset of blocks from the set of blocks that are classified into the first bin;
identifying a first block from the subset of blocks having a first drift time;
identifying a second block from the subset of blocks having a second drift time, the second drift time being less than the first drift time; and
identifying a third block from the subset of blocks having a third drift time, the third drift time being less than the second drift time;
wherein the first drift time, the second drift time, and the third drift time are based on a scan order of the set of blocks.

5. The memory sub-system of claim 4, wherein:
the first drift time is a highest drift time among the subset of blocks classified into the first bin; and
the second drift time is a lowest drift time among the subset of blocks classified into the first bin.

6. The memory sub-system of claim 1, wherein the performing of the BFEA scans on the scan targets comprises determining updated bin classifications for each of the first block, the second block, and the third block.

7. The memory sub-system of claim 6, wherein the determining of the updated bin classifications for each of the first block, the second block, and the third block comprises:
classifying the first block into a second bin;
classifying the second block into a third bin; and
classifying the third block into a fourth bin.

8. The memory sub-system of claim 7, wherein the updating of the bin classifications for other blocks in the subset of blocks comprises:
determining a second bin number corresponding to the second bin is greater than or equal to a third bin number corresponding to the third bin;
determining the third bin number is greater than or equal to a fourth bin number corresponding to the fourth bin; and
based on determining the second bin number is greater than or equal to the third bin number and determining the third bin number is greater than or equal to the fourth bin number, calculating a fifth bin for classifying a first portion of the subset of blocks based on an average of the second bin number and the third bin number;
classifying the first portion of the subset of blocks into the fifth bin;
calculating a sixth bin for classifying a second portion of the subset of blocks based on an average of the third bin number and the fourth bin number;
classifying the second portion of the subset of blocks into the sixth bin.

9. The memory sub-system of claim 7, wherein the updating of the bin classifications for other blocks in the subset of blocks comprises:
based on determining that a second bin number corresponding to the second bin is less than a third bin number corresponding to the third bin or that the third bin number is less than a fourth bin number corresponding to the fourth bin, calculating a fifth bin to associate with other blocks in the subset based on a median of: the second bin number, the third bin number, and the fourth bin number; and
classifying the other blocks in the subset of blocks with the fifth bin.

10. The memory sub-system of claim 1, wherein the operations further comprise:
determining read level voltage offsets for a block in the subset of blocks based on the updated bin classifications; and
applying the read level voltage offsets in one or more read operations directed at the block.

11. The memory sub-system of claim 1, wherein:
the scan targets are a first scan targets;
the subset of blocks is a first subset of blocks; and
the operations further comprise:
identifying second scan targets corresponding to a second bin of the multiple bins based on the scan pool, the second scan targets including a fourth block, a fifth block, and a sixth block from a second subset of blocks from the set of blocks that are associated with the second bin;
performing BFEA scans on the second scan targets; and
updating bin classifications for other blocks in the second subset of blocks based on a result of the BFEA scans on only the second scan targets.

12. A method comprising:
generating, by a processing device, a scan pool comprising a set of blocks of a memory device, each block in the set of blocks being classified into one of multiple predefined bins based on determined read level shifts of the set of blocks, each bin of the multiple bins having a corresponding set of read level voltage offsets;
identifying, by the processing device, scan targets for a first bin of the multiple predefined bins based on the scan pool, the scan targets including a first block, a second block, and a third block from a subset of blocks from the set of blocks that are classified into the first bin;
performing, by the processing device, block family error avoidance (BFEA) scans on only the scan targets; and
updating, by the processing device, bin classifications for other blocks in the subset of blocks based on a result of the BFEA scans on only the scan targets.

13. The method of claim 12, wherein generating the scan pool comprises:
accessing a scan queue comprising multiple blocks, the scan queue defining a scan order for BFEA scans; and
appending one or more other blocks to the scan queue.

14. The method of claim 13, wherein:
the generating of the scan pool is performed upon system power up; and
the scan queue is persistently stored prior to system power down.

15. The method of claim 12, wherein determining the scan targets for the first bin comprises:
identifying the subset of blocks from the set of blocks that are classified into the first bin;
identifying a first block from the subset of blocks having a first drift time;
identifying a second block from the subset of blocks having a second drift time, the second drift time being less than the first drift time; and
identifying a third block from the subset of blocks having a third drift time, the third drift time being less than the second drift time;
wherein the first drift time, the second drift time, and the third drift time are based on a scan order of the set of blocks.

16. The method of claim 15, wherein:
the first drift time is a highest drift time among the subset of blocks classified into the first bin; and
the second drift time is a lowest drift time among the subset of blocks classified into the first bin.

17. The method of claim 12, wherein the performing of the BFEA scans on the scan targets comprises:
classifying the first block into a second bin;
classifying the second block into a third bin; and
classifying the third block into a fourth bin.

18. The method of claim 17, wherein the updating of the bin classifications for other blocks in the subset of blocks comprises:
determining a second bin number corresponding to the second bin is greater than or equal to a third bin number corresponding to the third bin;
determining the third bin number is greater than or equal to a fourth bin number corresponding to the fourth bin; and
based on determining the second bin number is greater than or equal to the third bin number and determining the third bin number is greater than or equal to the fourth bin number, calculating a fifth bin for classifying a first portion of the subset of blocks based on an average of the second bin number and the third bin number;
classifying the first portion of the subset of blocks into the fifth bin;
calculating a sixth bin for classifying a second portion of the subset of blocks based on an average of the third bin number and the fourth bin number;
classifying the second portion of the subset of blocks into the sixth bin.

19. The method of claim 17, wherein the updating of the bin classifications for other blocks in the subset of blocks comprises:
based on determining that a second bin number corresponding to the second bin is less than a third bin number corresponding to the third bin or that the third bin number is less than a fourth bin number corresponding to the fourth bin, calculating a fifth bin to associate with other blocks in the subset based on a median of: the second bin number, the third bin number, and the fourth bin number; and
classifying the other blocks in the subset of blocks with the fifth bin.

20. A computer-readable storage medium comprising instructions that, when executed by a processing device, configure the processing device to perform operations comprising:
generating a scan pool comprising a set of blocks of a memory device, each block in the set of blocks being classified into one of multiple predefined bins based on determined read level shifts of the set of blocks, each bin of the multiple bins having a corresponding set of read level voltage offsets;
identifying scan targets for a first bin of the multiple predefined bins based on the scan pool, the scan targets including a first block, a second block, and a third block from a subset of blocks from the set of blocks that are classified into the first bin;
performing block family error avoidance (BFEA) scans on only the scan targets; and
updating bin classifications for other blocks in the subset of blocks based on a result of the BFEA scans on only the scan targets.
